(19) United States
(12) Patent Application Publication
(10) Pub. No.: US 2017/0354983 A1
(43) Pub. Date: Dec. 14, 2017

(54) NOZZLE ASSEMBLY, EVAPORATION PLATING APPARATUS AND METHOD OF MANUFACTURING AN ORGANIC LIGHT EMITTING DIODE

(71) Applicants: Boe Technology Group Co., Ltd., Beijing (CN); Hefei Xinsheng Optoelectronics Technology Co., Ltd., Anhui (CN)

(72) Inventor: Qinghua Zou, Beijing (CN)

(21) Appl. No.: 15/522,857

(22) PCT Filed: Sep. 20, 2016
(86) PCT No.: PCT/CN2016/099433

§ 371 Date: Apr. 28, 2017

(30) Foreign Application Priority Data
Nov. 27, 2015 (CN) 201510849666.9

(51) Int. Cl. B05B 9/00; H01L 51/00; H01L 51/56; B05B 1/20

(52) U.S. Cl. CPC B05B 9/002; B05B 1/20; H01L 51/001; H01L 51/56

(57) ABSTRACT

A nozzle assembly, an evaporation plating apparatus, and a method of manufacturing an organic light emitting diode device is provided. A first heating element is arranged in the hollow cavity in the sidewall of the nozzle. When organic material is vapor deposited, the first heating element can perform heating to raise the temperature of the peripheral wall of the nozzle to be substantially the same as or slightly higher than the temperature of the evaporation plating chamber, thereby maintaining the temperature in the nozzle within a suitable range so that it is neither too low to cause the organic material to condense in the nozzle nor too high to carbonize the organic material.

### RELATED APPLICATIONS

The present application is the U.S. national phase entry of PCT/CN2016/099433, with an international filing date of Sep. 20, 2016, which claims the benefit of Chinese Patent Application No. 201510849666.9, filed on Nov. 27, 2015, the entire disclosures of which are incorporated herein by reference.

### TECHNICAL FIELD

The present application relates to the technical field of organic light emitting diodes, and particularly to a nozzle assembly, an evaporation plating apparatus and a method of manufacturing an organic light emitting diode device.

### BACKGROUND

At present, the main manufacturing process for an organic light emitting diode (OLED) is evaporation plating technology which mainly makes use of the principle of thermal evaporation of an organic material, i.e. the organic material is filled into a heating source and heated in a vacuum environment, such that the solid organic material is melted and volatilized or sublimated to form a gaseous state, and the gas flow of the organic material is deposited on a glass substrate to form layers of organic thin film, thereby preparing an OLED device.

The gas flow of the organic material flows out of the crucible via the nozzle of the heating source. However, since the manufacturing procedure is unstable or the solidification temperatures of some materials are close to the gaseous temperatures thereof, once the local temperature of the nozzle is low, the gaseous material is liable to slowly condense at the nozzle opening, so that the nozzle opening slowly becomes smaller until it is completely clogged. In this case, the evaporation plating rate of the organic material detected by a rate detection system usually gradually decreases, and the temperature of the heating source is gradually increased in order to keep the rate constant, whereas the excessively high temperature would cause deterioration of the material in property, even cracking and carbonization thereof. On the other hand, in case that a linear heating source is used, the deposition rate decreases, and consequently the amount of material deposited on the substrate is reduced and the film thickness is decreased, which affects the performance of the OLED device and reduces the yield of the product. In addition, for the above reasons, it is often required to open the cavity to treat the clogged nozzle and to replace the deteriorated material, which reduces the utilization rate of equipment and increases the production cost.

The nozzle assemblies of the current linear heating sources are all independent components made of titanium metal and have a high height. As shown in FIG. 1, a heating wire 4 for maintaining the temperature of a nozzle 2 is generally designed at a corner position formed between a body 1 and a support base plate 5 due to the fixing demand, such that the heat radiated from the heating wire 4 is mainly concentrated in the lower part of the nozzle, while the upper part of the nozzle 2 can obtain heat only by means of conduction of titanium metal and heat radiation. As a result, the temperature of the upper part, in particular the top of the nozzle 2 is relatively low and is difficult to control accurately.

### SUMMARY

In view of the deficiencies in the prior art, the present application provides improved nozzle assembly, evaporation plating apparatus and method of manufacturing an organic light emitting diode device, which attempt to effectively prevent the evaporation plated organic material from condensing at the nozzle.

According to a first aspect of the present invention, there is provided a nozzle assembly including a body provided with a nozzle. The body is further provided with a hollow cavity located in a sidewall of the nozzle, and a first heating element is arranged in the hollow cavity.

In some embodiments, the body is provided with a plurality of nozzles distributed in a straight line direction, and two sides of each of the plurality of nozzles are provided with one hollow cavity, respectively.

In some embodiments, the first heating element is a heating wire extending parallel to the straight line direction.

In some embodiments, each of the hollow cavities is provided with at least two parallel heating wires.

In some embodiments, the body is made of a titanium alloy or an aluminum alloy.

In some embodiments, the body is an integral structure.

In some embodiments, the body includes a first member, a second member, and a third member. The second member and the third member abut on two opposite sides of the first member respectively, and the two opposite sides are provided with a first groove, respectively, and the second member and the third member are provided with a second groove corresponding to the first groove, respectively, such that one first groove and one second groove are combined into one hollow cavity.

In some embodiments, the nozzle assembly further includes a temperature control device for controlling the first heating element to perform heating when it is detected that the temperature at the nozzle is below a set threshold.

In some embodiments, the hollow cavity is arranged close to a spout of the nozzle.

According to a second aspect of the present invention, there is provided an evaporation plating apparatus including the above-described nozzle assembly.

In some embodiments, the evaporation plating apparatus further includes a crucible chamber in communication with the nozzle and a second heating element for heating the crucible chamber.

According to a third aspect of the present invention, there is provided a method of manufacturing an organic light emitting diode device, which evaporates and plates an organic material using the above-described evaporation plating apparatus and enables the first heating element to generate heat upon evaporation plating.

As can be known from the above technical solutions, the present invention provides a nozzle assembly, an evaporation plating apparatus, and a method of manufacturing an organic light emitting diode device. Since a first heating element is arranged in the hollow cavity located in the sidewall of the nozzle, when the organic material is evaporated and plated, the first heating element can perform heating, and the heat generated thereby is radiated to the peripheral wall of the hollow cavity and is not easy to dissipate, such that the temperature of the peripheral wall of the nozzle is raised to be substantially the same as or slightly higher than the temperature of the evaporation plating chamber, thereby maintaining the temperature in the nozzle within a suitable range, so that it is neither too low to cause the organic material to condense in the nozzle nor too high to carbonize the organic material. Meanwhile, since the organic material does not condense in the nozzle, it is not necessary to halt the evaporation plating apparatus to clean the nozzle, improving the utilization rate of equipment. Since the organic material no longer condenses at the nozzle or is no longer carbonized at a high temperature, the thickness of the organic material layer formed by evaporation plating conforms to the design requirement, and the material is not deteriorated, thereby improving the performance of the organic light emitting diode device.

### BRIEF DESCRIPTION OF THE DRAWINGS

In order to more clearly illustrate the technical solutions of embodiments of the present invention, the drawings required for describing the embodiments are briefly introduced below. Apparently, the drawings described below are just some embodiments of the present invention. Those ordinarily skilled in the art may further obtain other embodiments based on these drawings without spending inventive efforts. It is to be recognized that the drawings are not necessarily drawn to scale, rather that some components may be exaggerated to highlight the inventive aspects of the present invention.

FIG. 1 is a schematic side view of the structure of a nozzle assembly provided by the prior art;

FIG. 2 is a schematic side view of the structure of an integral nozzle assembly provided by an embodiment of the present invention;

FIG. 3 is a schematic structural view of the nozzle assembly of FIG. 2 cut along line AA of FIG. 2;

FIG. 4 is a schematic structural view of the nozzle assembly of FIG. 2 cut along line BB in FIG. 2;

FIG. 5 is a schematic side view of the structure of a modular nozzle assembly provided by another embodiment of the present invention;

FIG. 6 is a schematic structural view of an evaporation plating apparatus provided by embodiments of the present invention.

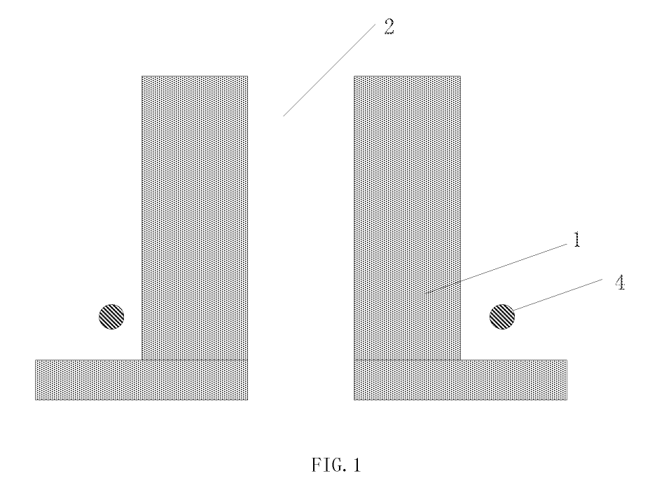

### DETAILED DESCRIPTION

Example implementations of the present invention will be further described below with reference to the accompanying drawings. The following embodiments are only intended to illustrate the technical solution of the present invention more clearly rather than to limit the protection scope of the present invention.

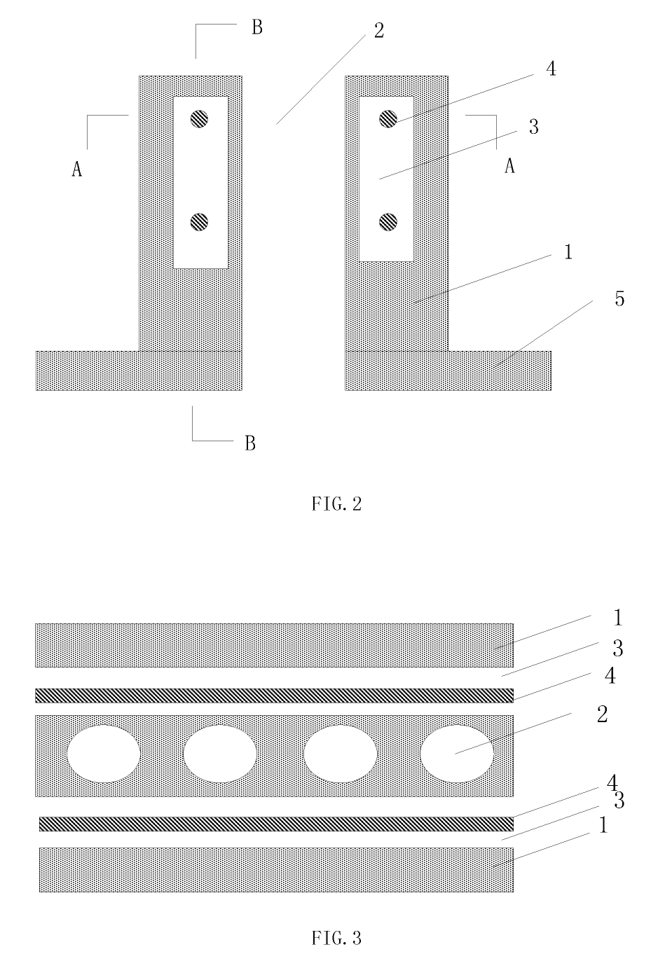

In an embodiment of the present invention, there is provided a nozzle assembly. As shown in FIGS. 2, 3 and 4, the nozzle assembly comprises a body 1 provided with a nozzle 2. The body 1 is further provided with a hollow cavity 3 located in the sidewall of the nozzle 2, and a first heating element 4 is arranged in the hollow cavity 3. In the present application, the nozzle 2 is a hollow passage which is enclosed by the material that makes up the body 1 and used for ejecting the evaporation planting material. It comprises two openings, one of which is generally in communication with the evaporation plating chamber of the evaporation plating apparatus.

With the above solution, since the first heating element 4 is provided in the hollow cavity 3 located in the sidewall of the nozzle 2, when an organic material is evaporated and planted, the first heating element 4 can perform heating to generate heat. Furthermore, since the heat in the hollow cavity is not easily dissipated, the heat generated by the first heating element 4 is radiated to the peripheral wall of the hollow cavity, such that the temperature of the peripheral wall of the nozzle 2 is raised to be substantially the same as or slightly higher than the temperature of the evaporation plating chamber, thereby maintaining the temperature of the nozzle 2 within a suitable range so that it is neither too low to cause the organic material to condense in the nozzle nor too high to carbonize the organic material.

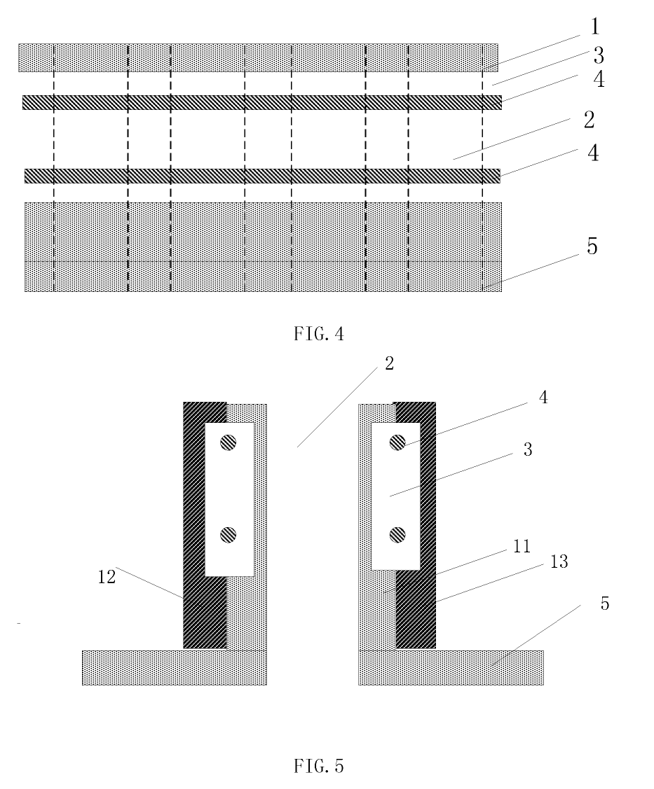

As shown in FIGS. 3 and 4, the body 1 is provided with a plurality of nozzles 2 distributed in a straight line direction (a direction from left to right as shown in the figure) (the nozzles are shown by multiple dotted lines in FIG. 4). Two sides of each of the plurality of nozzles 2 are provided with one hollow cavity 3, respectively. Since a plurality of nozzles are provided, the organic material can be evaporated simultaneously from the plurality of nozzles. Note that the straight line direction here only indicates that the plurality of nozzles are arranged substantially in a straight line direction, whereas it is also possible to arrange some of the nozzles offset from the straight line direction. By providing the hollow cavity, in which a first heating element is arranged, at two sides of the nozzle, respectively, the heating can be made uniform and the temperatures at two sides of the nozzle are substantially the same, which further prevents the organic material from condensing in the nozzle. Optionally, the hollow cavity is arranged close to the spout of the nozzle.

As also shown in FIGS. 3 and 4, the first heating element 4 is a heating wire extending parallel to the above straight line direction, wherein the “parallel” refers to “substantial parallel”, i.e. no exact parallel is required. The heating wire is in the form of a strip and extends in a direction identical with the direction in which the plurality of nozzles 2 are arranged, which obviously further makes it easier to keep the temperatures of the respective nozzles uniform. Moreover, at least two parallel heating wires are provided in each hollow cavity 3 in FIGS. 2, 3 and 4. In the case where the hollow cavity 3 has a longer extension length in the direction in which the nozzle ejects the organic material, a plurality of heating wires may be arranged in the hollow cavity 3, and the arrangement of a plurality of heating wires is more advantageous to keep the heating uniform. The opening of the nozzle 2 may have an elliptical shape as shown in FIG. 3, and may also have other shapes depending on actual needs.

The body 1 is generally made of a titanium alloy or an aluminum alloy so as to facilitate heat transfer and also to prevent melting of metal.

As shown in FIG. 2, the body 1 may be an integral structure. The body 1 can be manufactured by machining a nozzle 2 in the central portion of a metal block and then machining a hollow cavity 3 within the sidewalls on two sides of the nozzle. The body 1 may also be a modular structure as shown in FIG. 5, that is, the body 1 comprises a first member 11, a second member 12, and a third member 13. The second member 12 and the third member 13 abut on two opposite sides of the first member 11 respectively, and the first member 11 is provided with a nozzle 2 between the two opposite sides. The sidewalls on the two opposite sides are provided with a first groove respectively, and the second member 12 and the third member 13 are provided with a second groove that matches the first groove, respectively, such that one first groove and one second groove can be combined into one hollow cavity 3. The body 1 shown in FIG. 5 can be manufactured by machining a nozzle in the central portion of a metal block, machining a groove structure on the outer side of the sidewall of the nozzle, machining a groove structure on one side of the other two metal blocks, and then bonding two metal blocks together so that the groove structures thereof are just aligned to form a hollow structure. It is possible to select the integral or modular structure based on actual needs and production conditions.

In some embodiments, the nozzle assembly may further comprise a temperature control device (not shown in the figures) for controlling the first heating element to perform heating when it is detected that the temperature at the nozzle 2 is below a set threshold. The temperature control device comprises, for example, a temperature measuring device and a control device. The temperature measuring device is, for example, a digital thermometer for detecting the temperature at the nozzle and sending it to the control device. The control device comprises, for example, a programmable logic device and corresponding software and firmware, and controls heating of the first heating element based on the detected temperature. The respective portions of the temperature control device may be arranged at any suitable positions as required.

The nozzle assembly may further comprise, for example, a support base plate 5 and other components, which will not be described here.

The nozzle assembly of the present application is generally used in an evaporation plating apparatus and may also be used in other apparatuses.

In an embodiment of the present invention, there is provided an evaporation plating apparatus, which comprises the above-described nozzle assembly, and thus has the technical effect of achieving better evaporation plating. At the same time, since the organic material does not condense in the nozzle, it is not necessary to halt the evaporation plating apparatus to clean the nozzle, improving the utilization rate of equipment.

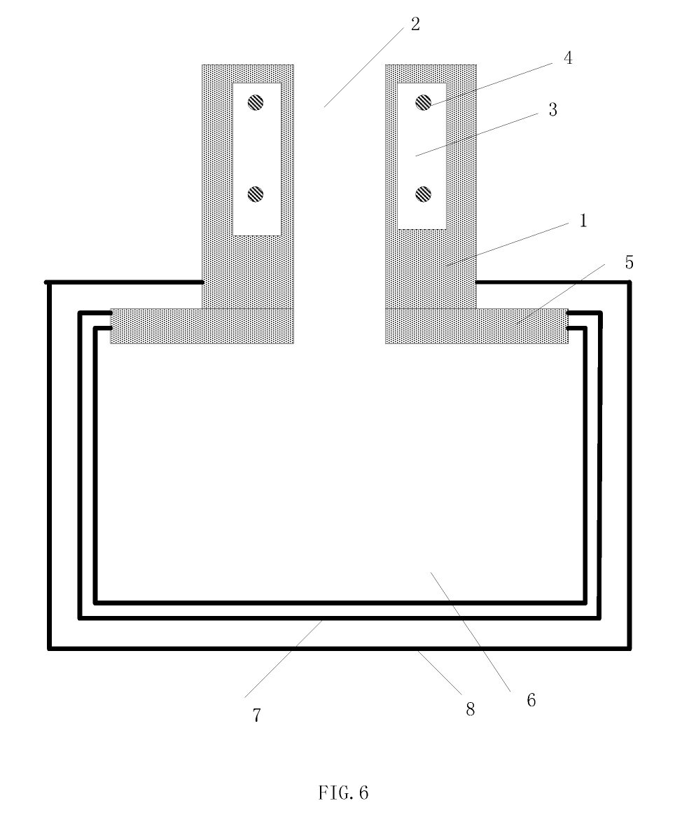

As shown in FIG. 6, the evaporation plating apparatus further comprises a crucible chamber 6 in communication with the nozzle 2 and a second heating element 7 for heating the crucible chamber 6 to supply the ejected organic material to the nozzle 2. The evaporation plating apparatus may further comprise components such as a condenser 8, a reflecting plate and so on, which will not be described here.

In an embodiment of the present invention, there is provided a method of manufacturing an organic light emitting diode device, which evaporates and plants an organic material using the above-described evaporation plating apparatus and controls the temperature at the nozzle by enabling the first heating element to generate heat upon evaporation plating. By this method, since the organic material no longer condenses at the nozzle and is no longer carbonized at a high temperature, the thickness of the organic material layer formed by evaporation plating is uniform and can meet the product specification requirement, and the material is not deteriorated, improving the performance of the organic light emitting diode device. Moreover, since the nozzle would not be clogged, the stability of the manufacturing procedure and the production efficiency are also improved. Of course, the manner of manufacturing an organic light emitting diode device may further include other steps depending on actual needs, which will not be described here.

Unless otherwise specified, the technical terms or scientific terms used in the present disclosure should be interpreted as common meanings understood by those skilled in the art of this field. The words such as “first”, “second” and the like used in the present disclosure do not denote any order, quantity, or importance, but rather are used to distinguish different constituent parts. The word such as “comprise” or “include” and the like means that an element or object preceding the word encompasses an element or object recited after the word and its equivalents, and does not exclude other elements or objects.

Finally, it is to be noted that the above embodiments are merely used for illustrating the technical solutions of the present invention, rather than limiting them. While the present application has been described in detail with reference to the foregoing embodiments, it will be understood by those ordinarily skilled in the art that, the technical solutions recited in the foregoing embodiments can still be modified, or some or all of the technical features can be equivalently substituted, and these modifications or substitutions not causing the essence of respective technical solutions to depart from the scope of the technical solutions of the embodiments of the present invention, should be encompassed within the scope of the claims and the specification of the present invention.

1. A nozzle assembly comprising a body provided with a nozzle, wherein the body is further provided with a hollow cavity located in a sidewall of the nozzle, and a first heating element is arranged in the hollow cavity.

2. The nozzle assembly according to claim 1, wherein the body is provided with a plurality of nozzles distributed in a straight line direction, and two sides of each of the plurality of nozzles are provided with one hollow cavity, respectively.

3. The nozzle assembly according to claim 2, wherein the first heating element is a heating wire extending parallel to the straight line direction.

4. The nozzle assembly according to claim 3, wherein each of the hollow cavities is provided with at least two parallel heating wires.

5. The nozzle assembly according to claim 1, wherein the body is made of a titanium alloy or an aluminum alloy.

6. The nozzle assembly according to claim 1, wherein the body is an integral structure.

7. The nozzle assembly according to claim 1, wherein the body comprises a first member, a second member and a third member, the second member and the third member abut on two opposite sides of the first member respectively, and the first member is provided with a nozzle between the two opposite sides and provided with a first groove on the two opposite sides, respectively; the second member and the third member are provided with a second groove corresponding to the first groove, respectively, such that one first groove and one second groove are combined into one hollow cavity.

8. The nozzle assembly according to claim 1, further comprising a temperature control device for controlling the first heating element to perform heating when it is detected that a temperature at the nozzle is below a set threshold.

9. The nozzle assembly according to claim 2, wherein the hollow cavity is arranged close to a spout of the nozzle.

10. An evaporation plating apparatus comprising the nozzle assembly according to claim 1.

11. The evaporation plating apparatus according to claim 10, further comprising a crucible chamber in communication with the nozzle and a second heating element for heating the crucible chamber.

12. A method of manufacturing an organic light emitting diode device, the method comprising: evaporating an organic material and planting the organic material using an evaporation plating apparatus having a body provided with a nozzle, wherein the body is further provided with a hollow cavity located in a sidewall of the nozzle, and a first heating element is arranged in the hollow cavity, and the first heating element generates heat upon evaporation plating.

13. The nozzle assembly according to claim 2, wherein the body comprises a first member, a second member and a third member, the second member and the third member abut on two opposite sides of the first member respectively, and the first member is provided with a nozzle between the two opposite sides and provided with a first groove on the two opposite sides, respectively; the second member and the third member are provided with a second groove corresponding to the first groove, respectively, such that one first groove and one second groove are combined into one hollow cavity.

14. The nozzle assembly according to claim 3, wherein the body comprises a first member, a second member and a third member, the second member and the third member abut on two opposite sides of the first member respectively, and the first member is provided with a nozzle between the two opposite sides and provided with a first groove on the two opposite sides, respectively; the second member and the third member are provided with a second groove corresponding to the first groove, respectively, such that one first groove and one second groove are combined into one hollow cavity.

15. The nozzle assembly according to claim 4, wherein the body comprises a first member, a second member and a third member, the second member and the third member abut on two opposite sides of the first member respectively, and the first member is provided with a nozzle between the two opposite sides and provided with a first groove on the two opposite sides, respectively; the second member and the third member are provided with a second groove corresponding to the first groove, respectively, such that one first groove and one second groove are combined into one hollow cavity.

16. The nozzle assembly according to claim 2, further comprising a temperature control device for controlling the first heating element to perform heating when it is detected that a temperature at the nozzle is below a set threshold.

17. The nozzle assembly according to claim 3, further comprising a temperature control device for controlling the first heating element to perform heating when it is detected that a temperature at the nozzle is below a set threshold.

18. The nozzle assembly according to claim 4, further comprising a temperature control device for controlling the first heating element to perform heating when it is detected that a temperature at the nozzle is below a set threshold.

19. An evaporation plating apparatus, comprising the nozzle assembly according to claim 2.

20. A method of manufacturing an organic light emitting diode device, wherein an organic material is evaporated and planted using the evaporation plating apparatus according to claim 18, and the first heating element generates heat upon evaporation plating.
